(19) United States
(12) Patent Application Publication
(10) Pub. No.: US 2026/0280503 A1
(43) Pub. Date: Sep. 17, 2026

(54) Dual-Segment Backend

(71) Applicant: Allegro MicroSystems, LLC, Manchester, NH (US)

(72) Inventors: Steven Daubert, Bedford, NH (US); Srujan Shivanakere, Nashua, NH (US)

(73) Assignee: Allegro MicroSystems, LLC, Manchester, NH (US)

(21) Appl. No.: 19/078,501

(22) Filed: Mar. 13, 2025

(51) Int. Cl. H03F 3/45; H03F 3/68

(52) U.S. Cl. CPC H03F 3/45273; H03F 3/68; H03F 2200/375; H03F 2200/441; H03F 2200/462

(57) ABSTRACT

A semiconductor device includes a front-end circuit configured to generate an input signal is described. The semiconductor device also includes a first amplifier circuit having a first amplifier to receive the input signal and provide an unclamped signal. The semiconductor device also includes a second amplifier circuit having a second amplifier and a clamping circuit. The second amplifier receives the input signal, and the clamping circuit clamps an output from the second amplifier in response to the output exceeding a threshold (or trimming) value. The semiconductor device also includes a combiner circuit configured to receive the unclamped signal and the clamped signal and to produce a combined signal based on the unclamped signal and the clamped signal. The combined signal has one sensitivity at or below the threshold value and a second sensitivity above the threshold value. A trimming method for the semiconductor device is also described.

### BACKGROUND

A current sensor device can detect a current and output a voltage. The output voltage's relationship to the detected current has a given resolution (or sensitivity). In some cases, a current sensor may have two or more segments in its output response. Some current sensors applications rely on the ability to sense lower currents with one resolution (or sensitivity) and sense higher currents with another resolution (or sensitivity). However, conventional current sensors may experience delays and errors at the transition point between the two resolutions (or sensitivities). This can prevent use of the current sensor for the full output range.

### SUMMARY

In one aspect, a semiconductor device includes a front-end circuit configured to generate an input signal. The device also includes a first amplifier circuit having a first amplifier to receive the input signal and provide an unclamped signal. The device also includes a second amplifier circuit having a second amplifier and a clamping circuit. The second amplifier receives the input signal, and the clamping circuit clamps an output from the second amplifier in response to the output exceeding a threshold (or trimming) value. The device also includes a combiner circuit configured to receive the unclamped signal and the clamped signal and to produce a combined signal based on the unclamped signal and the clamped signal. The combined signal having a first sensitivity for output at or below the threshold value and a second sensitivity for output exceeding the threshold value.

The semiconductor device may be part of an electronic system, for example, a microchip or a digital device. The semiconductor device may be embodied in an integrated circuit (IC), for example, but not limited to, a magnetic field sensor IC, or a current sensor IC.

The combiner circuit may receive an offset correction signal, and the combined signal is produced based on the offset correction signal also. The offset correction signal may correct at least one offset in one or more of the first amplifier circuit and the second amplifier circuit.

The input signal may also include an offset correction signal to correct at least one offset in the front-end circuit.

The front-end circuit may include a signal transducer to generate a signal based on a detected current. The signal transducer may include a current sensor. The current sensor may be part of an IC package.

The front-end circuit may include a test signal input.

The front-end circuit may include a front-end amplifier to produce the input signal.

The clamping circuit may include a fully differential opamp to set the threshold value.

The clamping circuit may include a current-mirror feedback.

The semiconductor device may also include an additional amplifier circuit having an additional amplifier and an additional clamping circuit to provide an additional clamped signal. The additional amplifier receives the input signal. The additional clamping circuit clamps an output from the additional amplifier in response to the output exceeding an additional threshold value. The combiner circuit also receives the additional clamping circuit output and produces the combined signal additionally based on the additional clamping circuit output.

In another aspect, an integrated circuit provides the ability for a current sensor to sense lower currents with one resolution (or sensitivity) and higher currents with a second, different resolution (or sensitivity). The IC includes a front-end circuit to generate an input signal. The front-end circuit has a signal transducer to generate a transducer output based on a detected current. The front-end circuit also has a front-end amplifier to produce a front-end signal based on the transducer output; and a front-end offset correction signal generator to produce a front-end offset correction signal. The input signal is based on the front-end offset correction signal and the front-end signal. The integrated circuit also has a dual segment backend circuit. The dual segment backend circuit includes a first amplifier circuit having a first amplifier to provide an unclamped signal. The first amplifier receives the input signal. The dual segment backend circuit also includes a second amplifier circuit having a second amplifier and a clamping circuit to provide a clamped signal. The second amplifier receives the input signal, and the clamping circuit clamps an output from the second amplifier in response to the output exceeding an adjustable or trimmable threshold value. The dual segment backend circuit includes a first offset correction signal generator to produce a first offset correction signal and a combiner circuit to produce a combined signal based on the unclamped signal, the clamped signal and the first offset correction signal. The combined signal has a first sensitivity for output at or below the threshold value and a second sensitivity for output exceeding the threshold value. The dual segment backend circuit also includes a backend amplifier to produce an output signal based on the combined signal.

In additional aspect, a method is provided for trimming the offset of the integrated circuit above. The method includes disabling the front-end amplifier to produce a first output signal value and setting the first offset correction signal generator to produce the first offset correction signal to trim the first output signal value. Then, the front-end amplifier is enabled to produce a second output signal value and the front-end offset correction signal generator is set to produce the front-end offset correction signal to trim the second output signal value.

### DESCRIPTION OF THE DRAWINGS

The foregoing features may be more fully understood from the following description of the drawings. The drawings aid in explaining and understanding the disclosed technology. Since it is often impractical or impossible to illustrate and describe every possible embodiment, the provided figures depict one or more illustrative embodiments. Accordingly, the figures are not intended to limit the scope of the broad concepts, systems and techniques described herein. Like numbers in the figures denote like elements.

FIG. 1 shows a current sensor in accordance with an embodiment.

FIG. 2 illustrates a two-part response curve for a current sensor having two resolutions.

FIG. 3 demonstrates a current sensor in accordance with another embodiment.

FIG. 4 demonstrates an amplifier with a trimmable clamp in accordance with a further embodiment.

FIG. 5 illustrates an additional current sensor in accordance with another embodiment.

FIG. 6 is a flow diagram of a trimming method for a current sensor in accordance with an embodiment.

FIG. 7 illustrates a multiple segmented backend for a current sensor in accordance with an embodiment.

### DETAIL DESCRIPTION

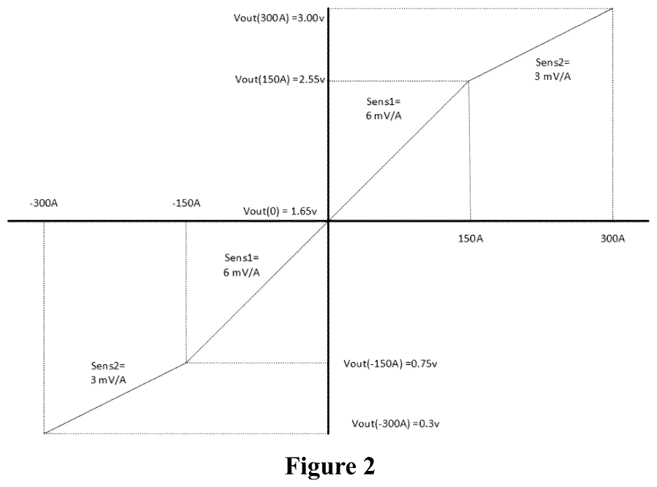

Described herein are techniques to provide a current sensor with the ability to sense lower currents with higher resolution (or sensitivity) and relax the resolution for higher currents. The current sensor's output has two (such as shown in FIG. 2) or more segments in its output response. The output transitions from one segment to another without any delay and is applicable for the full bandwidth (or output range) of the part.

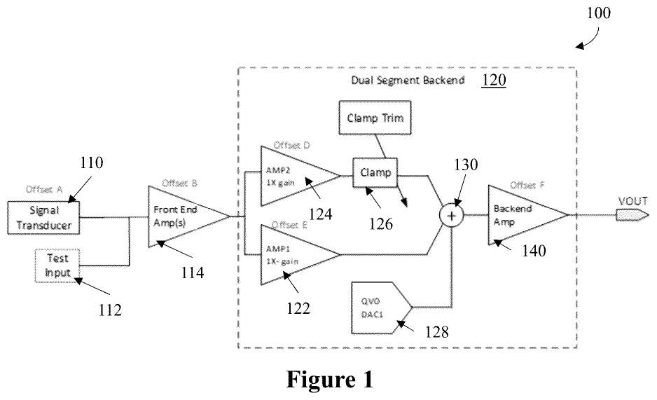

FIG. 1 shows a current sensor circuit 100 that uses an offset trimming method. As shown, a signal transducer 110 is configured to generate a signal based on a current being tested. Alternatively, a test input 112 may be used to provide the signal. The signal is passed through a front end amplifier 114 and the amplified signal is provided to AMP1 122 and AMP2 124. From AMP1, the signal is provided to a combiner 130.

A clamp 126 is provided in the path from AMP2 124 to combiner 130. The clamp 126 is configured to clamp the signal from AMP2 124 once it reaches a given threshold. The resulting signal (whether clamped or not) is sent to the combiner 130. The combiner 130 adds the two signals and provides the output to the backend amp 140. Once amplified by the backend amp 140, the final output is provided as VOUT.

At various stages of the current signal, offsets may be introduced into the signal, such as Offset A from signal transducer 110, Offset B from front end amplifier 114, Offset D from AMP2 124, Offset E from AMP1 122 and Offset F from backend amp 140. QVO DAC1 128 may provide a signal to the combiner 130 in order to correct for the various offsets.

The addition of clamp 126 introduces challenges in offset trimming methodology. The overall offset that ends up at the input of the backend amplifier 140 is trimmed out by using an offset correction DAC (e.g., QVO DAC1 128). In FIG. 1, the overall offset at the input of backend amp 140 would be equal to 2*(A+B)+D+E. Hence, the offset correction DAC may be programmed to generate an equally opposite voltage to trim out the offset. However, in the presence of sufficiently large input signals to turn on the clamp 126, the offsets through AMP2 124 also get nullified and this will lead to QVO DAC1 128 overcompensating. This overcompensation in turn leads to increased output error in the second (lower gain) segment. Additionally, the transition point between the various segments is prone to inconsistencies and error.

The transducer 110 may be a transducer coil. In some embodiments, the transducer 110 may also include or be replaced with one or more magnetic field sensing elements, which may include, but are not limited to a Hall effect transducer or a magnetoresistance sensor, such as a Tunnel Magnetoresistance (TMR) element or a magnetic tunnel junction element (MTJ).

In contrast, various embodiments provide an improved response curve to the detected current. FIG. 2 illustrates a two-part response curve for a current sensor having two resolutions. During a lower gain section, e.g., Sens1 where the detected current is between −150 A and 150 A, the output voltage follows a first slope. When the detected current exceeds the threshold (e.g., +/−150 A), the response curve follows a second, different slope. Furthermore, the transition point between the two slopes is smooth and continuous.

The dual output segments are achieved by implementing two parallel paths in the backend stage. One is clamped at the transition voltage and the other remains unclamped. This cuts the amount of signal beyond the transition voltage to half which in-turn reduces the sensitivity by half resulting in dual segments.

Various embodiments use a dual-segment backend architecture with clamped and un-clamped paths in parallel. Additionally, the architecture can be extended beyond 2 segments by adding more parallel paths and clamps at different voltage levels.

The clamp architecture may also provide a variable (or trimmable) clamp voltage to enable configurability of the transition voltage and ensure accurate transition voltage over process and temperature variations. The embodiments may be used with a new offset trim methodology to minimize (or lessen) the offset in both segments of the output. This can be achieved by separating the offsets in the front-end from the backend and then trimming them individually.

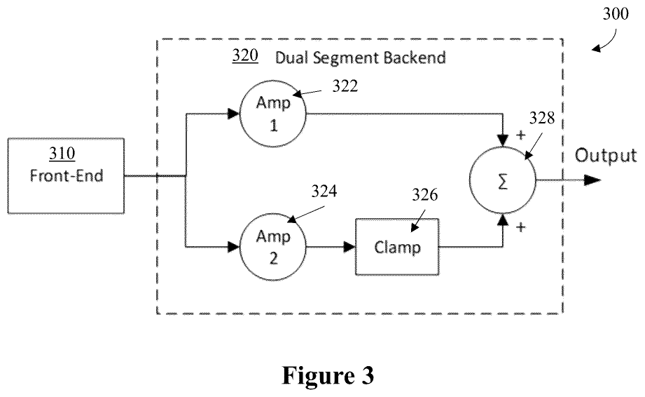

FIG. 3 demonstrates a current sensor circuit 300 in accordance with an embodiment. The current sensor circuit 300 is an integrated circuit that implements a dual segmented output using the summation of two signals, one of which is clamped by clamp 326 at the transition point between the two segments. This implementation is fully differential up to the output summing amplifier 328, which also acts as a differential to a single end converter leading to single ended output. The output can remain fully differential in some embodiments.

As shown, the current sensor circuit 300 has a front-end 310 circuit that is used to generate an input signal. The front-end 310 may be a transducer coil and/or one or more magnetic field sensing elements, which may include, but are not limited to a Hall effect transducer or a magnetoresistance sensor, such as a Tunnel Magnetoresistance (TMR) element or a magnetic tunnel junction element (MTJ).

The current sensor circuit 300 also has a dual segment backend 320 which includes a first leg (or amplifier circuit) having amplifier AMP1 322 to provide an unclamped signal and a second leg (or amplifier circuit) having AMP2 324 and clamping circuit 326 to provide a clamped signal. The clamping circuit clamps an output from the second amplifier when the output exceeding a threshold value.

The current sensor circuit 300 also includes a combiner circuit 328 which receives the unclamped signal and the clamped signal and produces a combined signal based on the unclamped signal and the clamped signal. The combined signal has a first sensitivity for output at or below the threshold value and a second sensitivity for output exceeding the threshold value. The threshold value may be an adjustable or trimmable threshold.

In the current sensor circuit 300, the gain of amplifiers AMP1 322 and AMP2 324 may be set to 1X. An advantage of this architecture is that it uses a sensitivity (gain) adjustment in one of the gain segments and the other gain segment is automatically adjusted based on the ratio of the gain between AMP1 322 and AMP2 324.

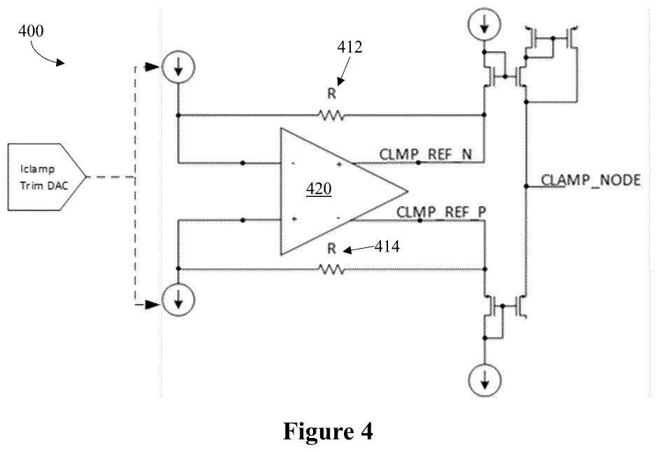

The clamp architecture may include a fully differential opamp with current inputs and resistive feedback to set the high and low clamp voltages as shown in FIG. 4. The high clamp reference voltage, CLMP_REF_P, and the low clamp reference, CLMP_REF_N, are connected to source follower type clamping circuits, with the n-channel clamp having current-mirror feedback to improve the clamping performance.

The clamp reference voltages are created from a current, Iclamp, and the resistors R 412, 414. The current Iclamp is derived from a bandgap voltage and a similar type of resistor, the clamping voltage is the bandgap voltage scaled by the resistor ratio. The fully differential opamp 420 used in the clamping circuit 400 may have an internal common mode feedback circuit which forces the output common mode voltage towards a value, VCM. The high clamp reference voltage is VCLMP_REF_P=Iclamp*R+VCM, and the low clamp reference voltage is VCLMP_REF_N=−Iclamp*R+VCM. The clamp level can be adjusted (or trimmed) by adjusting the Iclamp inputs to feedback R using a current DAC.

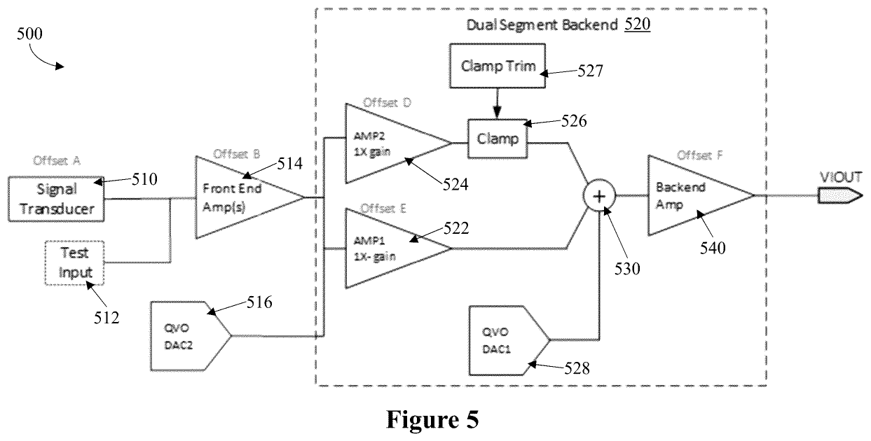

FIG. 5 illustrates an additional current sensor circuit 500 in accordance with another embodiment. The additional current sensor circuit 500 includes a DAC (QVO DAC2 516) which is configured to remove offsets before the offsets reach the dual segment backend 520. Accordingly, there are two offset correction DACs: QVO DAC1 530 and QVO DAC2 516.

The current sensor circuit 500 shown in FIG. 5 also includes a signal transducer 510 and a test input 512 which may be used to provide an input signal. The input signal is passed through a front end amplifier 514 and the amplified signal is provided to AMP1 522 and AMP2 524.

One path is provided from AMP2 524 to clamp 526. The resulting signal (whether clamped or not based on a threshold value) is sent to the combiner 530. The combiner 530 adds the two signals and provides the output to the backend amp 540 which generates the final output is provided as VOUT.

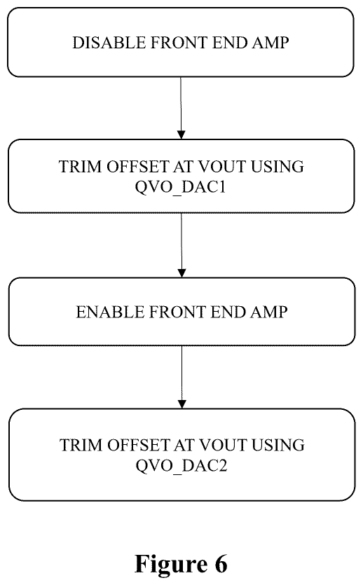

Current sensor circuit 500 uses a trimming method which may be performed during production using ATE (Automated Test Equipment). As shown in FIG. 6, the trimming method includes disabling Front End Amp. This sets the offset at VOUT to be equal to offsets D+E+F. The offset at VOUT is trimmed using QVO_DAC1 so that the QVO_DAC1 is equal to −(offsets D+E+F). Next, the trimming method includes enabling Front End Amp. This sets the offset at VOUT to be equal to offsets 2*(A+B). Finally, the offset at VOUT is trimmed using QVO_DAC2 so that QVO_DAC2 is equal to −(offsets A+B). Using this method, the error in the second segment due to offset trim is reduced from offset A+B+D to simply offset D. This allows a technique to be used to minimize the error in the second segment to just the offset of a unity gain buffer rather than the offset of the whole front end.

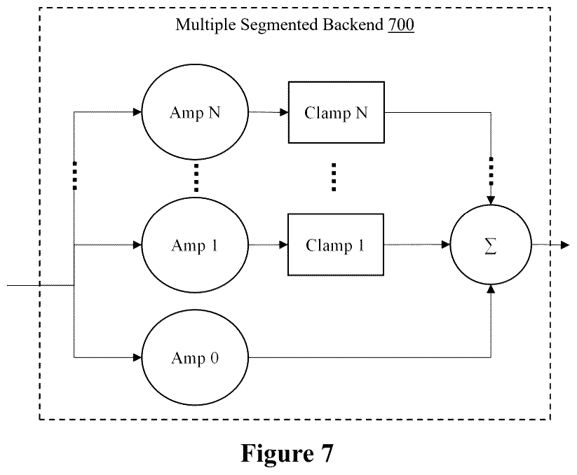

As noted above, the backend circuit may include multiple clamp circuits. FIG. 7 illustrates a multiple segmented backend 700 for a current sensor in accordance with such an embodiment. As shown, additional amplifier-clamp circuits are provided in parallel with the unclamped circuit. Each clamp (Clamp 1 through Clamp N) may be clamped at different threshold values in order to provide a response curve having multiple sensitivity regions. As with the dual segment backend, the combiner circuit may add the various amplifier-clamp circuits and the unclamped circuit together in order to produce an output signal.

Having described preferred embodiments, which serve to illustrate various concepts, structures, and techniques, which are the subject of this patent, it will now become apparent to those of ordinary skill in the art that other embodiments incorporating these concepts, structures and techniques may be used.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A integrated circuit, comprising:
a front-end circuit configured to generate an input signal;
a first amplifier circuit comprising a first amplifier to provide an unclamped signal, wherein the first amplifier is configured to receive the input signal;
a second amplifier circuit comprising a second amplifier and a clamping circuit to provide a clamped signal,
wherein the second amplifier is configured to receive the input signal, and
wherein the clamping circuit is configured to clamp an output from the second amplifier in response to the output exceeding a threshold value; and
a combiner circuit configured to receive the unclamped signal and the clamped signal and to produce a combined signal based on the unclamped signal and the clamped signal, the combined signal having a first sensitivity for output at or below the threshold value and a second sensitivity for output exceeding the threshold value.

2. The integrated circuit according to claim 1, wherein the combiner circuit is further configured to receive an offset correction signal, and to produce the combined signal further based on the offset correction signal.

3. The integrated circuit according to claim 2, wherein the offset correction signal is configured to correct at least one offset in one or more of the first amplifier circuit and the second amplifier circuit.

4. The integrated circuit according to claim 1, wherein the input signal further comprises an offset correction signal configured to correct at least one offset in the front-end circuit.

5. The integrated circuit according to claim 1, wherein the front-end circuit comprises a signal transducer configured to generate a signal based on a detected current.

6. The integrated circuit according to claim 1, wherein the front-end circuit comprises a test signal input.

7. The integrated circuit according to claim 1, wherein the front-end circuit comprises a front-end amplifier configured to produce the input signal.

8. The integrated circuit according to claim 1, wherein the clamping circuit comprises a fully differential opamp configured to set the threshold value.

9. The integrated circuit according to claim 1, wherein the clamping circuit comprises a current-mirror feedback.

10. The integrated circuit according to claim 1, further comprising an additional amplifier circuit comprising an additional amplifier and an additional clamping circuit to provide an additional clamped signal,
wherein the additional amplifier is configured to receive the input signal,
wherein the additional clamping circuit is configured to clamp an additional clamping circuit output from the additional amplifier in response to the additional clamping circuit output exceeding an additional threshold value; and
wherein the combiner circuit is further configured to receive the additional clamping circuit output and to produce the combined signal additionally based on the additional clamping circuit output.

11. A integrated circuit, comprising:
a front-end circuit configured to generate an input signal, wherein the front-end circuit comprises:
a signal transducer configured to generate a transducer output based on a detected current,
a front-end amplifier configured to produce a front-end signal based on the transducer output; and
a front-end offset correction signal generator configured to produce a front-end offset correction signal,
wherein the input signal is based on the front-end offset correction signal and the front-end signal; and
a dual segment backend circuit, the dual segment backend circuit comprising:
a first amplifier circuit comprising a first amplifier to provide an unclamped signal, wherein the first amplifier is configured to receive the input signal;
a second amplifier circuit comprising a second amplifier and a clamping circuit to provide a clamped signal, wherein the second amplifier is configured to receive the input signal, and wherein the clamping circuit is configured to clamp an output from the second amplifier in response to the output exceeding a threshold value;
a first offset correction signal generator configured to produce a first offset correction signal;
a combiner circuit configured to produce a combined signal based on the unclamped signal, the clamped signal and the first offset correction signal, the combined signal having a first sensitivity for output at or below the threshold value and a second sensitivity for output exceeding the threshold value; and
a backend amplifier configured to produce an output signal based on the combined signal.

12. A method of trimming the integrated circuit according to claim 11, the method comprising:
disabling the front-end amplifier to produce a first output signal value;
setting the first offset correction signal generator to produce the first offset correction signal to trim the first output signal value;
enabling the front-end amplifier to produce a second output signal value; and
setting the front-end offset correction signal generator to produce the front-end offset correction signal to trim the second output signal value.
